(19) United States
(12) Patent Application Publication
(10) Pub. No.: US 2017/0045672 A1
(43) Pub. Date: Feb. 16, 2017

(54) DISPLAY DEVICE

(71) Applicant: Samsung Display Co., Ltd., Yongin-si (KR)

(72) Inventors: Dae Ho LEE, Seoul (KR); Myung Hwan KIM, Yongin-si (KR); Han Joon YOO, Seoul (KR); Jae Sang LEE, Asan-si (KR); Hee-Keun LEE, Suwon-si (KR)

(21) Appl. No.: 15/073,210

(22) Filed: Mar. 17, 2016

(30) Foreign Application Priority Data
Aug. 13, 2015 (KR) 10-2015-0114625

(51) Int. Cl. F21V 8/00; G02F 1/1362; G02F 1/1368; H01L 27/12; G02F 1/1333

(52) U.S. Cl. CPC G02B 6/0056; H01L 27/1218; G02F 1/133377; G02F 1/1368; G02F 1/136227; G02B 6/0055; G02F 2001/133531

(57) ABSTRACT

An exemplary embodiment provides a display device that includes a substrate including a bent portion, a polarizer disposed below the substrate, a thin film transistor disposed on the substrate, and a pixel electrode connected to the thin film transistor, wherein the polarizer includes an extending portion extended to the bent portion, and the extending portion is bent along the bent portion.

### RELATED APPLICATIONS

This application claims priority to and the benefit of Korean Patent Application No. 10-2015-0114625 filed in the Korean Intellectual Property Office on Aug. 13, 2015, the entire contents of which are incorporated herein by reference.

### BACKGROUND

(a) Field

The described technology relates generally to a display device.

(b) Description of the Related Art

A liquid crystal display is a widely-used type of flat panel display devices and generally includes two display panels on which field generating electrodes, such as a pixel electrode and a common electrode, are formed and a liquid crystal layer interposed therebetween.

The liquid crystal display generates an electric field in a liquid crystal layer by applying a voltage to the field generating electrodes to determine orientations of liquid crystal molecules of the liquid crystal layer and control polarization of incident light, thereby displaying an image.

A technique of forming a cavity in a pixel and filling the cavity with liquid crystals to implement a liquid crystal display has been developed. Although two sheets of substrates are used in a conventional liquid crystal display, this technique forms constituent elements on one substrate, thereby reducing weight, thickness, and the like of the device.

When using a micrometer-level thin substrate in the liquid crystal display, the substrate could be broken, or there may be a problem, such as a disconnection, due to cracks of a pad stacked on the substrate.

The above information disclosed in this Background section is only for enhancement of understanding of the background of the described technology and therefore may contain information that does not form the prior art that is already known in this country to a person of ordinary skill in the art.

### SUMMARY

The described technology provide a display device having advantages of reinforcing a weakness of the substrate.

An exemplary embodiment a display device may include a substrate including a bent portion, a polarizer disposed below the substrate, a thin film transistor disposed on the substrate, and a pixel electrode connected to the thin film transistor, wherein the polarizer includes an extending portion extended to the bent portion, and the extending portion is bent along the bent portion.

The bent portion and the extending portion may be disposed at a left or right side, or both sides, of the substrate.

The display device may further include a backlight unit, wherein the bent portion and the extending portion may be bent to cover a side surface of the backlight unit.

The substrate may include a display area, and the display area may be extended to the bent portion covering the side surface of the backlight unit.

The polarizer may include one or more furrows for bending that may correspond to bending parts.

A cross-sectional shape of the furrow for bending may be a triangular or semicircular shape.

The furrow for bending may include a plurality of furrows arranged in a line.

The display device may further include a common electrode facing the pixel electrode, a roof layer disposed on the common electrode, a liquid crystal layer formed with a plurality of microcavities including a liquid crystal molecule and formed between the pixel electrode and the roof layer, and a capping layer disposed on the roof layer.

The bent portion and the extending portion may be bent to cover a side and back surface of the backlight unit.

The polarizer may include two furrows for bending corresponding to bending parts, and the two furrows for bending may be separated from each other by a thickness of the backlight unit.

The display device may further include a common electrode facing the pixel electrode, a roof layer disposed on the common electrode, a liquid crystal layer formed with a plurality of microcavities including a liquid crystal molecule and formed between the pixel electrode and the roof layer, and a capping layer disposed on the roof layer.

The bent portion and the extending portion may be disposed at an upper or lower side, or both sides, of the substrate.

The display device may further include a backlight unit, wherein the bent portion and the extending portion may be bent to cover a side surface of the backlight unit.

The substrate may include a display area, and the display area may be extended to the bent portion covering the side surface of the backlight unit.

The polarizer may include one or more furrows for bending and corresponding to bending parts.

A cross-sectional shape of the furrow for bending may be a triangular or semicircular shape.

The furrow for bending may include a plurality of furrows arranged in a line.

The display device may further include a common electrode facing the pixel electrode, a roof layer disposed on the common electrode, a liquid crystal layer formed with a plurality of microcavities including a liquid crystal molecule and formed between the pixel electrode and the roof layer, and a capping layer disposed on the roof layer.

The bent portion and the extending portion may be bent to cover a side and back surface of the backlight unit.

The polarizer may include two furrows for bending and corresponding to bending parts, and the two furrows for bending may be separated from each other by a thickness of the backlight unit.

According to the exemplary embodiments, it is possible to solve the problems that may occur in the substrate such as tearing of the substrate, or a disconnection problem.

### BRIEF DESCRIPTION OF THE DRAWINGS

FIG. 1 is a top plan view of a substrate before being bent in a liquid crystal display according to an exemplary embodiment.

FIG. 2 is a top plan view of a substrate of which the left side is bent in a liquid crystal display according to an exemplary embodiment.

FIG. 3 is a cross-sectional view taken along the line III-Ill of FIG. 2.

FIG. 4 is a schematic drawing showing a furrow for bending of a lower polarizer of FIG. 3.

FIG. 5 is a top plan view of region A of FIG. 2.

FIG. 6 is a cross-sectional view taken along the line VI-VI of FIG. 5.

FIG. 7 is a cross-sectional view taken along the line VII-VII of FIG. 5.

FIG. 8 is a cross-sectional view schematically showing a liquid crystal display according to an exemplary embodiment.

FIG. 9 is a schematic drawing showing a furrow for bending of a lower polarizer of FIG. 8.

FIG. 10 and FIG. 11 are schematic drawings showing a furrow for bending of a lower polarizer of a liquid crystal display according to an exemplary embodiment.

FIG. 12 is a top plan view of a substrate of which the top side is bent in a liquid crystal display according to an exemplary embodiment.

FIG. 13 is a cross-sectional view taken along the line X III-X III of FIG. 12.

FIG. 14 is a schematic drawing showing a furrow for bending of a lower polarizer of FIG. 13.

### DETAILED DESCRIPTION

Hereinafter, exemplary embodiments are described in detail with reference to the accompanying drawings. As those skilled in the art would realize, the described embodiments may be modified in various different ways, all without departing from the spirit or scope of the present disclosure. On the contrary, exemplary embodiments introduced herein are provided to sufficiently transfer the spirit of the present disclosure to those skilled in the art.

In the drawings, the thickness of layers, films, panels, regions, etc., are exaggerated for clarity. When a layer is referred to as being “on” another layer or substrate, it may be directly on the other layer or substrate or may be between two layers or substrates. Like reference numerals designate like elements throughout the specification.

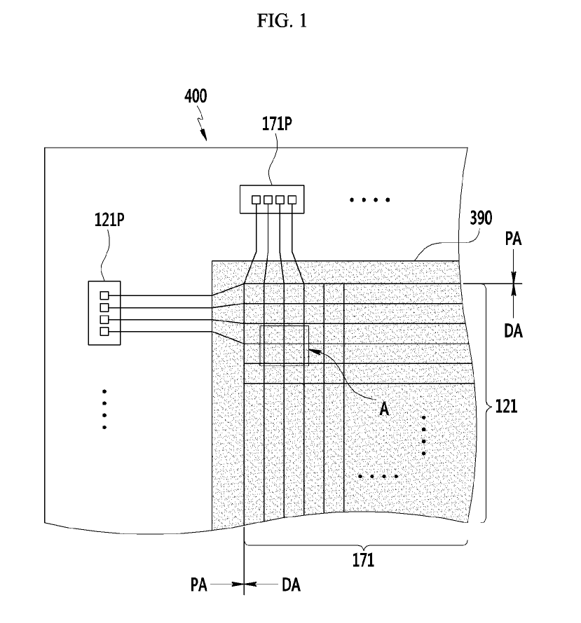

First, a bent portion 110B of a substrate, an extending portion 12B of a polarizer, and an approximate stack structure of a liquid crystal display according to an exemplary embodiment of the present disclosure are described with reference to FIGS. 1 to 4.

FIG. 1 is a top plan view of a substrate before being bent in a liquid crystal display according to an exemplary embodiment.

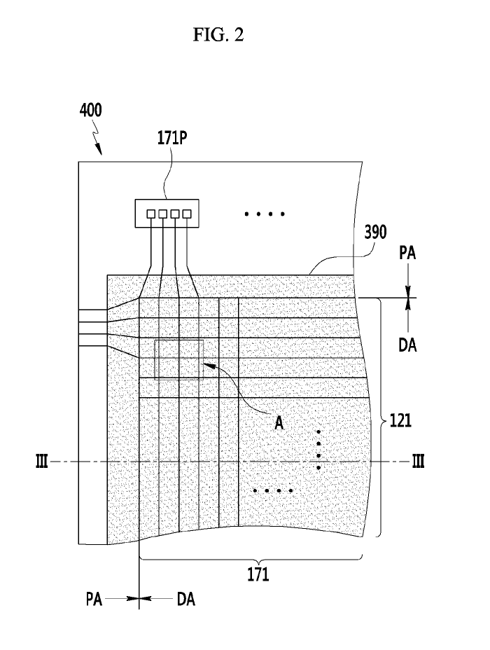

FIG. 2 is a top plan view of a substrate in which the left side is bent in a liquid crystal display according to an exemplary embodiment.

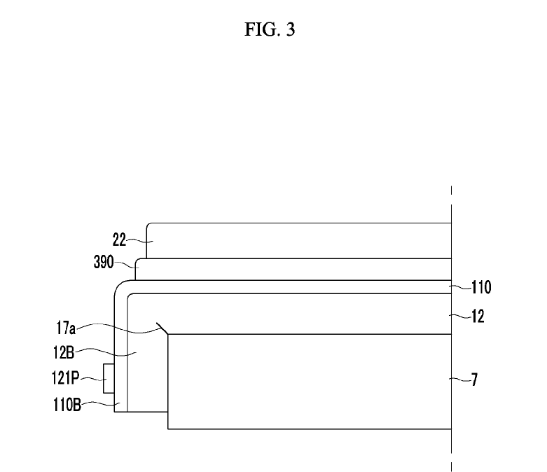

FIG. 3 is a cross-sectional view taken along the line of FIG. 2.

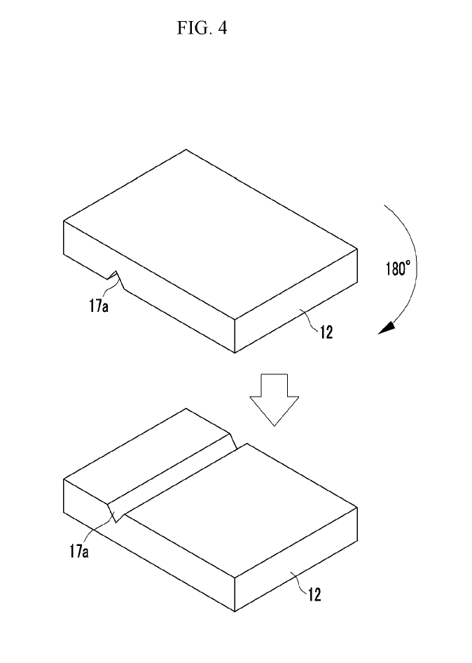

FIG. 4 is a schematic drawing showing a furrow for bending of a lower polarizer of FIG. 3.

Referring to FIG. 1 and FIG. 4, the liquid crystal display according to the present exemplary embodiment may include a liquid crystal panel assembly 400, a gate driver (not shown) and a data driver (not shown) connected thereto, a gray voltage generator (not shown) connected to the data driver, a light source unit (not shown) emitting light to the liquid crystal panel assembly 400, a light source driver (not shown) controlling the light source unit, and a signal controller (not shown) controlling them.

The gate driver or the data driver may be formed on the liquid crystal panel assembly 400, and may be formed as a separate integrated circuit chip.

A substrate 110 of the liquid crystal panel assembly 400 includes a display area DA and a peripheral area PA positioned to surround the display area DA. The display region DA is a region where an image is outputted, and in the peripheral region PA, the aforementioned gate driver or data driver is formed, or a gate pad portion 121P including a gate pad, a data pad portion 171P including a data pad, or the like, which is a portion connected to an external circuit, is positioned. The gate pad is a wide portion positioned at an end of a gate line 121, and the data pad is a wide portion positioned at an end of a data line 171.

The lower polarizer 12 is formed below the substrate 110, and a backlight unit 7 is formed below the lower polarizer 12.

The backlight unit 7 may include a light source, a light guide plate, a reflecting plate, and an optical sheet. However, the above-mentioned elements are shown only in an integral part in FIG. 3. Light provided from the light source is provided to the liquid crystal display panel, which is at the top, through the light guide plate, the reflecting plate, and the optical sheet. Depending on the exemplary embodiment, a luminance enhancing film formed by repeatedly stacking two layers having different reflective indexes among the optical sheets may not be included. In the case in which a polarizing plate used in the liquid crystal display panel is not an absorption type of polarizing plate, but is a reflection type of polarizing plate, the luminance enhancing film may not be included.

The substrate 110 includes the bent portion 110B as shown in FIG. 2 and FIG. 3. The gate pad portion 121P may be formed on the bent portion 110B. The bent portion 110B is bent to cover all or a portion of a side surface of the backlight unit 7. The peripheral area PA of a left side of the substrate 110 is bent. Though it may vary among embodiments, in the present exemplary embodiment, a right, an upper, or a lower side of the substrate 110 may be bent, and the substrate 110 may be bent to a portion of the display area DA over the peripheral area PA. In this case, images may be output on the bent portion 110B of the substrate 110 corresponding to the side of the backlight unit 7.

A lower polarizer 12 disposed below the substrate 110 includes the extending portion 12B extended to the bent portion 110B, and the extending portion 12B of the lower polarizer 12 is bent along the bent portion 110B. The extending portion 12B of the lower polarizer 12 is also bent to cover all or a portion of a side surface of the backlight unit 7.

Referring to FIG. 3 and FIG. 4, the lower polarizer 12 includes a furrow for bending 17a corresponding to a bending part of the lower polarizer 12. A cross-sectional shape of the furrow for bending 17a may be triangular, and the furrow for bending 17a may be a connected furrow. The furrow for bending 17a may be formed as a cut of the lower polarizer 12 by half-cut technology and so on using a laser, a cutter, etc. In this case, a folding degree of the lower polarizer 12 may be controlled by adjusting a width, an angle, and so on of the furrow for bending 17a, so controlling a curvature of the bent portion 110B is possible. A cross-sectional shape of the furrow for bending 17a may be triangular like the present exemplary embodiment, or may be various plane figure shapes. The furrow for bending 17a may be a connected furrow like the present exemplary embodiment, or may be configured by a plurality of furrows separated from each other and arranged in a line.

According to another embodiment, the extending portion 12B of the lower polarizer 12 may be bent without the use of a furrow for bending 17a. That is, the lower polarizer 12 may be bent directly, and the furrow for bending 17a may be omitted.

The extending portion 12B extending to the bent portion 110B of substrate 110 may support the substrate 110. When the plastic substrate has a thin thickness in the micrometer level, the substrate may be easy to tear when it is bent, or disconnection may be generated due to cracking of pads stacked on the substrate. But the problems mentioned above may be solved by the extension portion 12B of the lower polarizing plate 12 supporting the substrate 110. Furthermore, by making omission of the reinforcing film or the like for supporting the substrate 110 possible, the process cost may be reduced.

A capping layer 390 is disposed on the substrate 110, and an upper polarizer 22 is disposed on the capping layer 390.

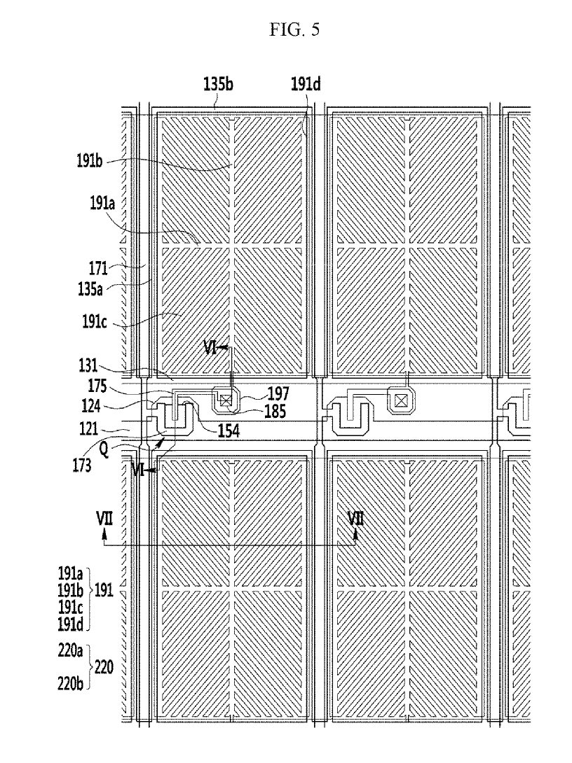

Details of the stack structure of the substrate 110 to the capping layer 390 are described later with reference to FIG. 5 to FIG. 7. When the substrate 110 is bent in the peripheral area PA as in the present exemplary embodiment, the capping layer 390 and the upper polarizer 22 are located on the substrate 110 only to the boundary of the bending portion 110B and not located on the bending portion 110B. In other words, when removing the capping layer 390 and the upper polarizer 22 on the peripheral area PA for connecting the driver and the pad portion, both the capping layer 390 and the upper polarizer 22 on the bending portion 110B may be removed. However, when the substrate 110 is bent to a portion of the display area DA over the peripheral area PA for outputting images on the bent portion 110B of the substrate 110 corresponding to the side of the backlight unit 7, the capping layer 390 and the upper polarizer 22 may be extended on the bending portion 110B.

Hereinafter, the constituent elements of the liquid crystal display in the display area DA are described in detail with reference to FIG. 5 to FIG. 7.

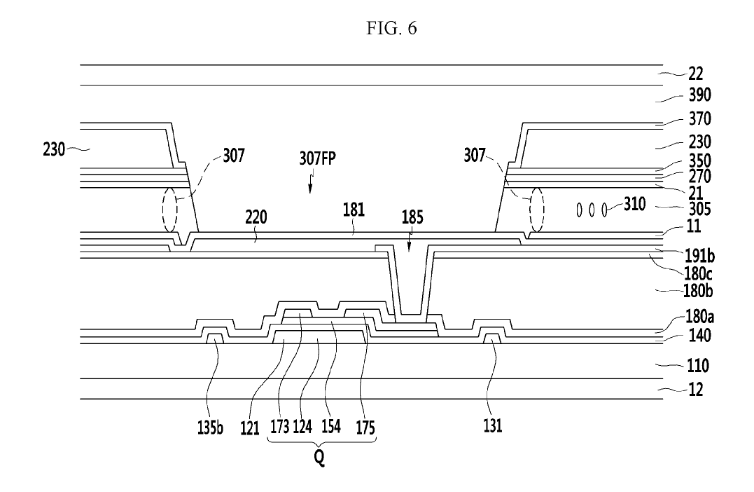

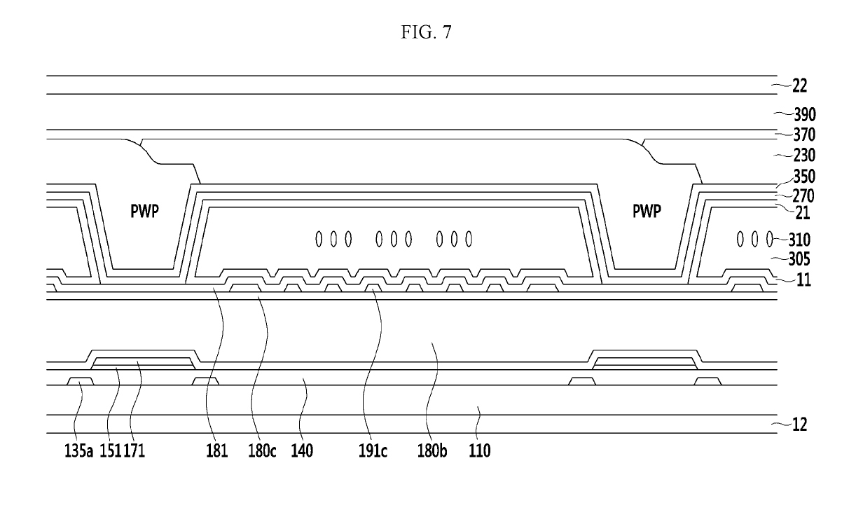

FIG. 5 is a top plan view of region A of FIG. 2. FIG. 6 is a cross-sectional view taken along the line VI-VI of FIG. 5. FIG. 7 is a cross-sectional view taken along the line VII-VII of FIG. 5.

FIG. 5 shows a 2×2 pixel portion as a center portion of a plurality of pixels, and these pixels may be repeatedly arranged up/down and right/left in the liquid crystal display according to an exemplary embodiment.

Referring to FIG. 5 to FIG. 7, a lower polarizer 12 is formed below a substrate 110, and a gate line 121 and a storage electrode line 131 are formed on a substrate 110 made of transparent glass or plastic. The gate line 121 includes a gate electrode 124. The storage electrode line 131 is mainly extended in a horizontal direction, and transfers a predetermined voltage such as a common voltage Vcom. The storage electrode line 131 includes a pair of vertical storage electrode portions 135a substantially extended to be perpendicular to the gate line 121, and a horizontal storage electrode portion 135b connecting ends of the pair of vertical storage electrode portions 135a to each other. The vertical and horizontal storage electrode portions 135a and 135b have a structure surrounding a pixel electrode 191.

A gate insulating layer 140 is formed on the gate line 121 and the storage electrode line 131. A semiconductor layer 151 positioned under a data line 171 and a semiconductor layer 154 positioned under a source/drain electrode and corresponding to a channel region of a thin film transistor Q are formed on the gate insulating layer 140.

A plurality of ohmic contacts may be formed between the semiconductor layer 151 and the data line 171, and between the semiconductor layer 154 under the source/drain electrode and corresponding to the channel region and the source/drain electrode, and are omitted in the drawings.

Data conductors 171, 173, and 175 including a source electrode 173, a data line 171 connected to the source electrode 173, and a drain electrode 175 are formed on the semiconductor layers 151 and 154 and the gate insulating layer 140. Here, the data line 171 is disposed between microcavities 305 adjacent to each other and located so as to overlap edges of the microcavity 305 with a light blocking member role.

The gate electrode 124, the source electrode 173, and the drain electrode 175 form a thin film transistor Q along with the semiconductor layer 154, and the channel of the thin film transistor Q is formed in the exposed portion of the semiconductor layer 154 between the source electrode 173 and the drain electrode 175.

A first interlayer insulating layer 180a is formed on the data conductors 171, 173, and 175 and the exposed semiconductor layer 154. The first interlayer insulating layer 180a may include an inorganic insulator such as silicon nitride (SiNx) and silicon oxide (SiOx).

A second interlayer insulating layer 180b and a third interlayer insulating layer 180c may be positioned on the first interlayer insulating layer 180a. The second interlayer insulating layer 180b may be formed of an organic material, and the third interlayer insulating layer 180c may include an inorganic insulator such as silicon nitride (SiNx) and silicon oxide (SiOx). When the second interlayer insulating layer 180b is formed of an organic material, a step may be reduced or removed. According to another exemplary embodiment, one or two of the first interlayer insulating layer 180a, the second interlayer insulating layer 180b, and the third interlayer insulating layer 180c may be omitted.

A contact hole 185 passing through the first interlayer insulating layer 180a, the second interlayer insulating layer 180b, and the third interlayer insulating layer 180c may be formed. The pixel electrode 191 positioned on the third interlayer insulating layer 180c may be electrically and physically connected to the drain electrode 175 through the contact hole 185. Hereafter, the pixel electrode 191 is described in detail.

The pixel electrode 191 may be made of a transparent conductive material such as ITO or IZO.

An overall shape of the pixel electrode 191 is a quadrangle, and the pixel electrode 191 includes cross stems configured by a horizontal stem 191a and a vertical stem 191b crossing the horizontal stem 191a. Further, the pixel electrode 191 is divided into four sub-regions by the horizontal stem 191a and the vertical stem 191b, and each sub-region includes a plurality of minute branches 191c. In the present exemplary embodiment, the pixel electrode 191 may further include an outer stem 191c1 connecting the minute branches 191c at right and left edges of the pixel electrode 191. In the present exemplary embodiment, the outer stem 191c1 is positioned at the right and left edges of the pixel electrode 191; however, it may be positioned to extend to an upper portion or a lower portion of the pixel electrode 191.

The minute branches 191c of the pixel electrode 191 form an angle of approximately 40° to 45° with the gate line 121 or the horizontal stem 191a. Further, the minute branches of two adjacent sub-regions may be perpendicular to each other. In addition, a width of each minute branch may be gradually increased, or a distance between the minute branches 191c may be varied.

The pixel electrode 191 includes an extension 197 that is connected at a lower end of the vertical stem 191b, has a larger area than the vertical stem 191b, and is electrically and physically connected to the drain electrode 175 through the contact hole 185 at the extension 197, thereby receiving a data voltage from the drain electrode 175.

The thin film transistor Q and the pixel electrode 191 described above are just examples, and the structure of the thin film transistor and a design of the pixel electrode may be modified in order to improve side visibility.

A light blocking member 220 is disposed on the pixel electrode 191 to cover a region where the thin film transistor Q is formed. The light blocking member 220 according to the present exemplary embodiment may be formed along a direction in which the gate line 121 extends. The light blocking member 220 may be formed of a material that blocks light (i.e., substantially or completely opaque).

An insulating layer 181 may be formed on the light blocking member 220, and the insulating layer 181 covering the light blocking member 220 may extend onto the pixel electrode 191. The insulating layer 181 may be formed of silicon nitride (SiNx) or silicon oxide (SiOx).

A lower alignment layer 11 is formed on the pixel electrode 191, and may be a vertical alignment layer. The lower alignment layer 11 may be a liquid crystal alignment layer made of a material such as polyamic acid, a polysiloxane, a polyimide, or the like, and may include at least one of generally used materials. Further, the lower alignment layer 11 may be a photoalignment layer.

An upper alignment layer 21 is disposed at a portion facing the lower alignment layer 11, and a liquid crystal layer is formed between the lower alignment layer 11 and the upper alignment layer 21. The liquid crystal layer is positioned between the lower alignment layer 11 and the upper alignment layer 21 and configured of a plurality of micro cavities 305 including liquid crystal materials including liquid crystal molecules 310. The microcavity 305 has an entrance region 307. The microcavities 305 may be formed along a column direction of the pixel electrode 191, that is, in the vertical direction. In the present exemplary embodiment, the alignment material forming the alignment layers 11 and 21 and the liquid crystal material including the liquid crystal molecules 310 may be injected into the microcavity 305 by using capillary force. In the present exemplary embodiment, the lower alignment layer 11 and the upper alignment layer 21 are merely distinguished according to position, and may be connected to each other as shown as in FIG. 7. The lower alignment layer 11 and the upper alignment layer 21 may be simultaneously formed.

The microcavity 305 is divided in the vertical direction by a plurality of liquid crystal injection portions 307FP positioned at a portion overlapping the gate line 121, thereby forming the plurality of microcavities 305 along a column direction of the pixel electrode 191, that is, in the vertical direction. Further, the microcavity 305 is also divided in the horizontal direction by a partition PWP, which is described later, thereby forming a plurality of microcavities 305 along the row direction of the pixel electrode 191, that is, the horizontal direction in which the gate line 121 extends. The formed microcavities 305 may respectively correspond to one or more pixel areas, and the pixel areas may correspond to a region displaying the image.

A common electrode 270 and a lower insulating layer 350 are positioned on the upper alignment layer 21. The common electrode 270 receives the common voltage, and generates an electric field together with the pixel electrode 191 to which the data voltage is applied to determine a direction in which the liquid crystal molecules 310 positioned in the microcavity 305 between the two electrodes are inclined. The common electrode 270 forms a capacitor with the pixel electrode 191 to maintain the received voltage even after the thin film transistor is turned off.

The lower insulating layer 350 may be formed of silicon nitride (SiNx) or silicon oxide (SiOx).

In the present exemplary embodiment, it is described that the common electrode 270 is formed on the microcavity 305, but in another exemplary embodiment, the common electrode 270 is formed under the microcavity 305, so that liquid crystal driving according to a coplanar electrode (CE) mode is possible.

In the present exemplary embodiment, a color filter 230 is disposed on the lower insulating layer 350. As shown in FIG. 7, among the color filters neighboring each other, the color filter 230 of one color forms the partition PWP. The partition PWP is disposed between the microcavities 305 neighboring in the horizontal direction. The partition PWP is a portion filling the separation space of the microcavities 305 neighboring in the horizontal direction. As shown in FIG. 7, the partition PWP completely fills the separation space of the microcavity 305; however, it is not limited thereto, and it may partially fill the separation space. The partition PWP may be formed along the direction in which the data line 171 extends.

The color filters 230 neighboring each other on the partition PWP may overlap. The boundary surface where the neighboring color filters 230 meet each other may be positioned at the portion corresponding to the partition PWP.

In the present exemplary embodiment, the color filter 230 and the partition PWP function as a roof layer supporting the microcavity 305 to maintain the shape thereof.

An upper insulating layer 370 is disposed on the color filter 230. The upper insulating layer 370 may be formed of silicon nitride (SiNx) or silicon oxide (SiOx). As shown in FIG. 6, the side surface of the color filter 230 may be covered with the upper insulating layer 370.

The capping layer 390 is positioned on the upper insulating layer 370. The capping layer 390 is also positioned at the liquid crystal injection portion 307FP and the entrance region 307 of the microcavity 305 exposed by the liquid crystal injection portion 307FP. The capping layer 390 includes an organic material or an inorganic material. Herein, the liquid crystal material is removed in the liquid crystal injection portion 307FP, and the liquid crystal material that remains after being injected into the microcavity 305 may remain at the liquid crystal injection portion 307FP.

A barrier layer (not shown) may be formed on the capping layer 390. The barrier layer (not shown) may include silicon nitride (SiNx) and the like to additionally prevent penetration by external moisture and oxygen. An upper polarizer 22 may be formed on the capping layer 390 or the barrier layer (not shown).

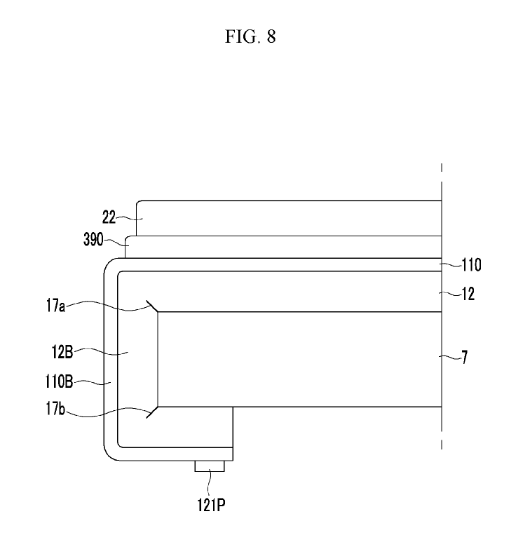

Hereinafter, a display device according to an exemplary embodiment is described with reference to FIGS. 8 to 11. The detailed descriptions of the same constituent elements of the liquid crystal display according to the exemplary embodiment described with reference to FIGS. 1 to 4 are omitted.

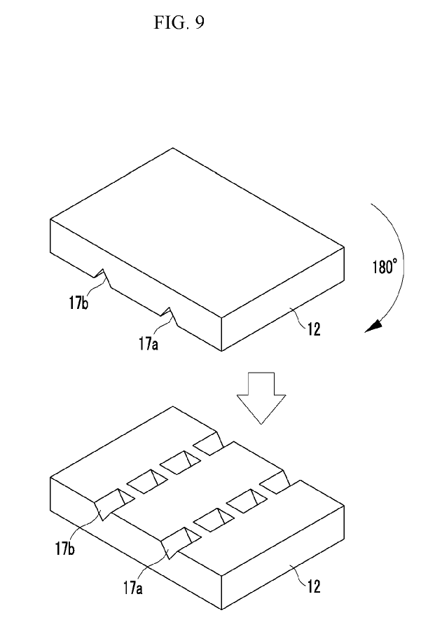

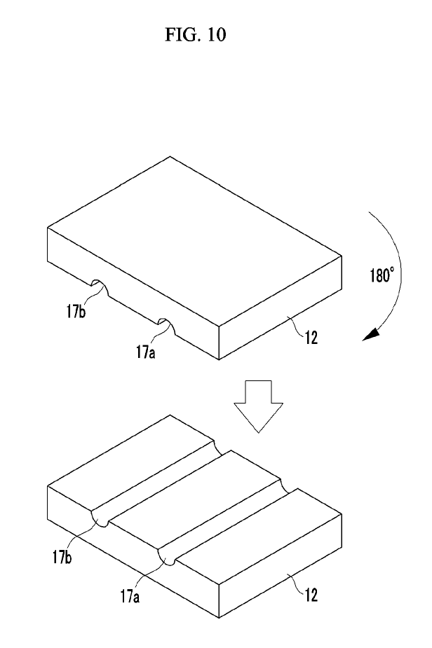

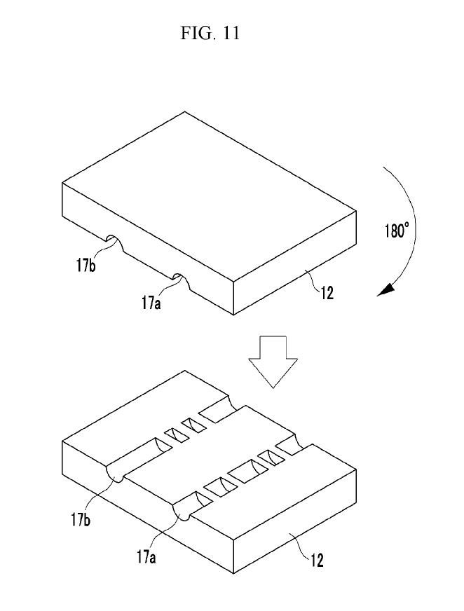

FIG. 8 is a cross-sectional view schematically showing a liquid crystal display according to an exemplary embodiment. FIG. 9 is a schematic drawing showing a furrow for bending of a lower polarizer of FIG. 8. FIG. 10 and FIG. 11 are schematic drawing showing a furrow for bending of a lower polarizer of a liquid crystal display according to an exemplary embodiment.

The substrate 110 includes the bent portion 110B as shown in FIG. 8. The bent portion 110B is bent to cover a side surface and a portion of the back surface of the backlight unit 7.

The lower polarizer 12 disposed below the substrate 110 includes an extending portion 12B extended to the bent portion 110B, and the extending portion 12B of the lower polarizer 12 is bent along the bent portion 110B. The extending portion 12B of the lower polarizer 12 is also bent to cover a side surface and a portion of the back surface of the backlight unit 7. In other words, the bent portion 110B of the substrate 110 and the extending portion 12B of the lower polarizer 12 wrap the backlight unit 7 together.

The lower polarizer 12 includes two furrows for bending 17a and 17b corresponding to bending parts of the lower polarizer 12. In other words, the two furrows for bending 17a and 17b are separated from each other by a thickness of the backlight unit 7. In the present exemplary embodiment, the furrow for bending 17a is configured by a plurality of furrows separated from each other and arranged in a line. Cross-sectional shapes of the furrows for bending 17a and 17b are triangular.

However, forms of the furrows for bending 17a and 17b are not limited thereto. The cross-sectional shapes of the furrows for bending 17a and 17b may be semicircular, and each furrow for bending 17a and 17b may be a connected furrow as shown in FIG. 10. Also, the cross-sectional shape of the furrows for bending 17a and 17b may be semicircular, and the furrows for bending 17a and 17b may be configured by a plurality of furrows separated from each other and arranged in a line. Furthermore, the forms of the furrows for bending 17a and 17b may be different from each other. In other words, sizes of the plurality of furrows arranged in a line configuring the furrows for bending 17a and 17b may be different, and spaces between them may be different.

In addition, the number of furrows for bending may be two or more depending on the type of the structure located below the lower polarizer 12, and a cross-sectional shape of the furrows for bending may be formed in various plane figure shapes. Also, the furrow for bending 17a may be a connected furrow or may be configured by a plurality of furrows separated from each other and arranged in a line. When there is a plurality of the furrows for bending, the forms of the furrows for bending may be different from each other.

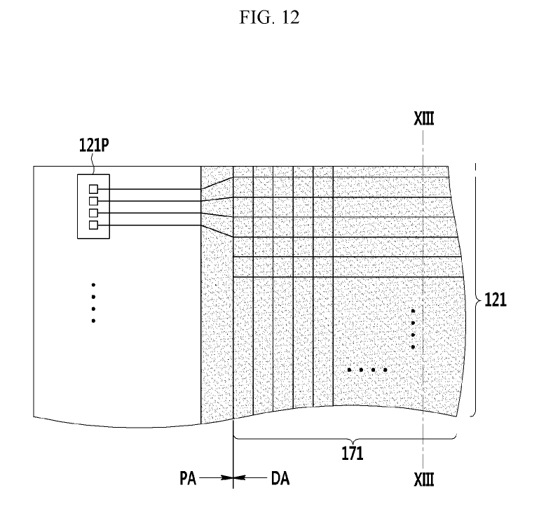

Hereinafter, a display device according to an exemplary embodiment is described with reference to FIGS. 12 to 14. The detailed descriptions of the same constituent elements of the liquid crystal display according to the exemplary embodiment described with reference to FIGS. 1 to 4 are omitted.

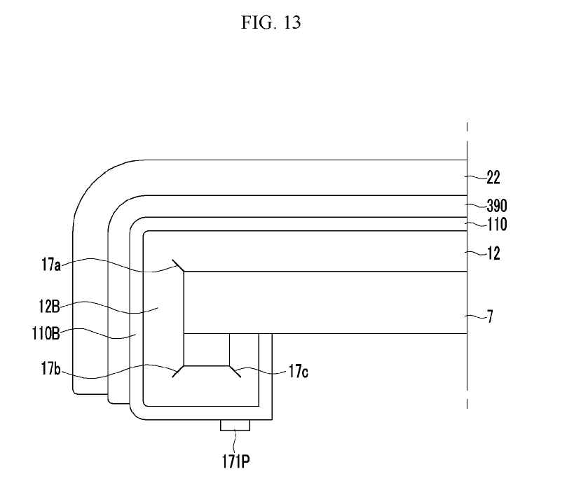

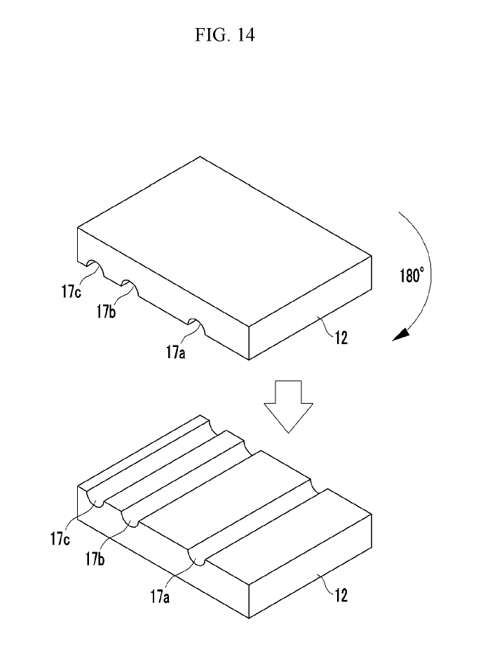

FIG. 12 is a top plan view of a substrate of which the top side is bent in a liquid crystal display according to an exemplary embodiment. FIG. 13 is a cross-sectional view taken along the line X III-X III of FIG. 12. FIG. 14 is a schematic drawing showing a furrow for bending of the lower polarizer of FIG. 13.

The substrate 110 includes the bent portion 110B as shown in FIG. 12 and FIG. 13. The data pad portion 171P may be positioned on the bent portion 110B. In the present exemplary embodiment, the upper side of the substrate 110 is bent, and the substrate 110 is bent to the portion of the display area DA over the peripheral area PA. The bent portion 110B is bent to cover a side surface and a portion of the back surface of the backlight unit 7, so in this case, images are output on the bent portion 110B of the substrate 110 corresponding to the side of the backlight unit 7.

The lower polarizer 12 disposed below the substrate 110 includes an extending portion 12B extended to the bent portion 110B, and the extending portion 12B of the lower polarizer 12 is bent along the bent portion 110B. The extending portion 12B of the lower polarizer 12 is also bent to cover a side surface and a portion of the back surface of the backlight unit 7.

The bent portion 110B of the substrate 110 and the extending portion 12B of the lower polarizer 12 may be bent as a U-shape depending on the type of the structure located below the lower polarizer 12. In the present exemplary embodiment, the lower polarizer 12 includes three furrows for bending 17a, 17b, and 17c. The three furrows for bending 17a, 17b, and 17c are located corresponding to a bending part of the lower polarizer 12, and the two furrows for bending 17a and 17b are separated from each other by a thickness of the backlight unit 7. The cross-sectional shapes of the furrows for bending 17a, 17b, and 17c are semicircular, and each furrow for bending 17a, 17b, and 17c is a connected furrow.

In addition, there may be three or more furrows for bending depending on the type of the structure located below the lower polarizer 12, and a cross-sectional shape of the furrow for bending may be formed in various plane figure shape. Also, the furrow for bending may be a connected furrow or may be configured by a plurality of furrows separated from each other and arranged in a line. When there is a plurality of the furrows for bending, the forms of the furrows for bending may be different from each other.

According to another embodiment, the extending portion 12B of the lower polarizer 12 may be bent without implementing the furrow for bending 17a. That is, the lower polarizer 12 may be bent directly, and the furrow for bending 17a may be omitted.

A capping layer 390 is disposed on the substrate 110, and an upper polarizer 22 is disposed on the capping layer 390. In the present exemplary embodiment, the substrate 110 is bent to a portion of the display area DA over the peripheral area PA for outputting images on the bent portion 110B of the substrate 110 corresponding to the side of the backlight unit 7, so the capping layer 390 and the upper polarizer 22 are extended on the bending portion 110B corresponding to the side of the backlight unit 7.

While this disclosure has been described in connection with exemplary embodiments, the present disclosure is not limited to the disclosed embodiments. On the contrary, the present disclosure covers various modifications and equivalent arrangements included within the spirit and scope of the appended claims.

### DESCRIPTION OF SYMBOLS

| PA | peripheral area | DA | display area |
|---|---|---|---|
| 7 | backlight unit | 12 | lower polarizer |
| 12B | extending portion | | |
| 17a, 17b, 17c | furrow for bending | 22 | upper polarizer |
| 110 | substrate | 110B | bent portion |
| 305 | microcavity | | |
| 307 | entrance region | 307FP | liquid crystal injection |
| | | | portion |
| 350 | lower insulation layer | 360 | roof layer |
| 370 | upper insulation layer | 390 | capping layer |

What is claimed is:

1. A display device comprising:
a substrate including a bent portion;
a polarizer disposed below the substrate;
a thin film transistor disposed on the substrate; and
a pixel electrode connected to the thin film transistor,
wherein the polarizer includes an extending portion extended to the bent portion, and the extending portion is bent along the bent portion.

2. The display device of claim 1, wherein
the bent portion and the extending portion are disposed at a left or right side, or both sides, of the substrate.

3. The display device of claim 2, further comprising
a backlight unit,
wherein the bent portion and the extending portion are bent to cover a side surface of the backlight unit.

4. The display device of claim 3, wherein
the substrate includes a display area, and
the display area is extended to the bent portion covering the side surface of the backlight unit.

5. The display device of claim 4, wherein
the polarizer comprises one or more furrows for bending that correspond to bending parts.

6. The display device of claim 5, wherein
a cross-sectional shape of the furrow for bending is a triangular or semicircular shape.

7. The display device of claim 6, wherein
the furrow for bending includes a plurality of furrows arranged in a line.

8. The display device of claim 5, further comprising:
a common electrode facing the pixel electrode;
a roof layer disposed on the common electrode;
a liquid crystal layer disposed in a plurality of microcavities between the pixel electrode and the roof layer; and
a capping layer disposed on the roof layer.

9. The display device of claim 5, wherein
the bent portion and the extending portion are bent to cover a side and back surface of the backlight unit.

10. The display device of claim 9, wherein
the polarizer comprises two furrows for bending corresponding to bending parts, and the two furrows for bending are separated from each other by a thickness of the backlight unit.

11. The display device of claim 10, further comprising:
a common electrode facing the pixel electrode;
a roof layer disposed on the common electrode;
a liquid crystal layer disposed in a plurality of microcavities between the pixel electrode and the roof layer; and
a capping layer disposed on the roof layer.

12. The display device of claim 1, wherein
the bent portion and the extending portion are disposed at an upper or lower side, or both sides, of the substrate.

13. The display device of claim 12, further comprising
a backlight unit,
wherein the bent portion and the extending portion are bent to cover a side surface of the backlight unit.

14. The display device of claim 13, wherein
the substrate includes a display area, and
the display area is extended to the bent portion covering the side surface of the backlight unit.

15. The display device of claim 14, wherein
the polarizer comprises one or more furrows for bending and corresponding to bending parts.

16. The display device of claim 15, wherein
a cross-sectional shape of the furrow for bending is a triangular or semicircular shape.

17. The display device of claim 16, wherein
the furrow for bending includes a plurality of furrows arranged in a line.

18. The display device of claim 17, further comprising:
a common electrode facing the pixel electrode;
a roof layer disposed on the common electrode;
a liquid crystal layer disposed in a plurality of microcavities between the pixel electrode and the roof layer; and
a capping layer disposed on the roof layer.

19. The display device of claim 17, wherein
the bent portion and the extending portion are bent to cover a side and back surface of the backlight unit.

20. The display device of claim 19, wherein
the polarizer comprises two furrows for bending corresponding to bending parts, and the two furrows for bending are separated from each other by a thickness of the backlight unit.
